(19) United States
(12) Patent Application Publication
(10) Pub. No.: US 2008/0157292 A1
(43) Pub. Date: Jul. 3, 2008

(54) High-stress liners for semiconductor fabrication

(75) Inventors: Manoj Mehrotra, Plano, TX (US); Stan Ashburn, McKinney, TX (US)

Correspondence Address: TEXAS INSTRUMENTS INCORPORATED, P O BOX 655474, M/S 3999, DALLAS, TX, 75265, US

(73) Assignee: Texas Instruments Inc.

(21) Appl. No.: 11/703,452

(22) Filed: Feb. 7, 2007

Related U.S. Application Data
(60) Provisional application No. 60/877,886, filed on Dec. 29, 2006.

(51) Int. Cl. H01L 21/31; H01L 29/00

(52) U.S. Cl. 257/637; 438/763; 257/E23.001; 257/E21.24

(57) ABSTRACT

A method for manufacturing a semiconductor device featuring a high-stress dielectric layer is disclosed. The method involves the deposition of a comparatively thick liner layer that exerts increased strain on an underlying gate and active areas, resulting in enhanced carrier mobility through the transistor and heightened transistor performance. The method also involves the amelioration of fabrication problems that might arise from the deposition of a comparatively thick liner layer by forming such layer with at least a partially direction deposition process. Also disclosed are semiconductor devices manufactured in accordance with the disclosed methods.

### REFERENCE TO RELATED APPLICATIONS

This application claims priority to Ser. No. 60/877,886 filed Dec. 29, 2006, which is entitled “High-Stress Liners for Semiconductor Fabrication.”

### FIELD OF THE INVENTION

The present disclosure relates generally to the fabrication of semiconductor devices, and more particularly to materials used as liners in the process of manufacturing semiconductor devices.

### BACKGROUND OF THE INVENTION

Integrated semiconductor circuits are built through a very intricate process of creating and interconnecting, on a semiconductor wafer, a multitude of devices comprised of layers of chemicals with various electromechanical properties. The steps for producing such devices are discussed herein as background for the discussion of the invention.

The process begins with a silicon wafer and the designation of doped moat areas, where NMOS and PMOS devices are to be created. The moat regions that will support PMOS devices are n-doped, and the moat regions that will support NMOS devices are p-doped. NMOS and PMOS regions are typically electrically isolated in order to prevent unintended conductivity. This isolation is implemented by forming an isolation structure between these regions, comprising a trench etched between the regions and filled with a dielectric material.

Following the formation of the isolation trench, a layer of controllably conductive material is selectively deposited to form the gate regions of transistors in each moat, where each gate connects a plurality of active transistor areas. These active transistor areas are doped accordingly: the active transistor areas of NMOS devices are n-doped, and the active transistor areas of PMOS devices are p-doped, such that the active transistor areas are isolated by the inversely doped moat region that serves as the channel. In many cases, the semiconductor is also subjected to silicidation in order to produce a silicide layer as an etch-stop protector on the active areas and gate in order to reduce contact resistivity.

Finally, a layer of dielectric material is deposited over the wafer and manufactured devices in order to protect and electrically insulate the devices. This layer is often preceded with a liner layer, which often comprises a nitride. Contact vias are selectively etched through the dielectric material in order to provide access to each gate and active transistor area; these contact vias are filled with one or more conductive metals, and the surface contact points for each metallized contact via are interconnected with other devices, for example, to produce a fully interconnected integrated circuit.

Several steps in this process involve the formation of a layer only in desired regions of the semiconductor. This selective deposition may be carried out by depositing the layer material across the entire surface of the semiconductor, followed by selectively removing the layer material from undesired regions. The selective removal step is often performed by a photolithography process. This process begins by forming a layer of photoresist material, which is sensitive to ultraviolet light, over the layer to be selectively removed. A photolithography mask is prepared, which contains a series of transparent regions corresponding to regions of undesired material, and opaque regions corresponding to regions of desired material. This photolithography mask is positioned over the photoresist layer, and ultraviolet light is directed toward the photolithography mask, such that the exposed regions of photoresist are selectively softened. The semiconductor is then exposed to a developer solution that selectively washes away the softened photoresist material, while leaving behind the unsoftened photoresist regions. This process selectively exposes regions of the underlying layer, which can be selectively removed by exposing the semiconductor to an etching solution that is chemically selective for the material of the underlying layer. Finally, the remaining photoresist material is removed, usually by an ashing process. The result of this photolithography process is a selectively deposited layer upon the semiconductor.

An additional feature of transistors manufactured in this manner is related to the performance of the transistors. The performance of a transistor is directly proportional to the mobility of the carriers (electrons or electron deficits) through the transistor, which in part determines the switching speed of the transistor and/or the voltage required to operate the transistor. An additional and desirable property of such transistors is mechanical stress, in the form of tensile or compressive strain, which increases the mobility of the carriers through the transistor. For NMOS devices embedded in an active region, the effect is optimal if a tensile stress is exerted on the channel region of the device.

It is known that a certain amount of desirable mechanical strain is imposed by a high stress liner such as a nitride layer that is deposited over the transistor gate and the active areas. The nitride layer has traditionally been used to serve as a contact via etch-stop and to protect the semiconductor from damage by external electrical and mechanical forces. However, more recent analysis has shown that these layers also impose a modicum of mechanical strain on the transistors that imparts the performance-enhancing effect described herein.

It is always desirable to make further improvements in fabrication techniques that result in higher-performance transistors.

### SUMMARY OF THE INVENTION

The following presents a simplified summary of the invention in order to provide a basic understanding of some aspects of the invention. This summary is not an extensive overview of the invention. It is intended neither to identify key or critical elements of the invention nor to delineate the scope of the invention. Rather, its primary purpose is merely to present one or more concepts of the invention in a simplified form as a prelude to the more detailed description that is presented later.

The present invention relates to manufacturing processes for devices like transistors on a semiconductor wafer. As noted above, transistors are conventionally constructed by forming a series of layers having different electrical properties, where one of the uppermost layers is a dielectric material that electrically insulates the circuit. After these layers are formed, an “etch” process is used to form vertical tunnels (called “contact vias”) through the dielectric layer, which are then filled with a conductive metal so that the transistors can be interconnected to other components to form a circuit. However, the etch process can potentially damage the transistors underneath the dielectric layer, so a “liner” layer is often formed below the dielectric layer that is resistant to the etch process.

It has been discovered that the dielectric layer and the liner, in addition to performing these tasks, also exert a mechanical strain on the transistor. In fact, this mechanical strain has been shown to speed up the propagation of the electrical signal through the transistor, thereby producing a faster and more energy-efficient transistor. Researchers are now exploring methods of increasing the magnitude of mechanical force applied to transistors in this manner in order to achieve further enhancement.

The present invention involves one such method of increasing the mechanical strain on a transistor. The method arises from the discovery that increasing the thickness of the liner layer results in a proportional increase in the strain imposed on the transistor. The invention therefore involves depositing a comparatively thick layer of liner material in order to increase the strain imposed on the transistor, thereby producing a faster transistor.

Two known problems with thick liner layers might have discouraged this fabrication technique, and the present invention suggests methods of circumventing these problems. First, in many conventional fabrication methods, the liner layer is formed with a “conformal” process in which the circuit is exposed to a gaseous form of the material that coats all exposed surfaces. However, when a layer is deposed conformally, it may create “voids” or pockets of empty space that are not filled with the material, and that interfere with the electrical properties of the circuit. Voids may occur more frequently between two transistors that are close together, where the side walls of the neighboring transistors form a deeper trench that a conformal process may not evenly fill. In light of the trend of semiconductor miniaturization, where circuits are built to be smaller and more densely packed with transistors, this problem is of growing importance. Moreover, void formation occurs more frequently as thicker layers of material are deposited.

In one embodiment the present invention suggests the reduction of this voiding problem by replacing the conformal process with a directional process, where the liner layer is formed by depositing material on the semiconductor in a substantially directional, downward manner. This allows spaces between nearby devices to fill in a substantially bottom-up manner, which promotes the complete filling of these spaces and thereby reduces void formation. In another embodiment of the invention, a hybrid process that is partly directional and partly conformal might also be useful without significantly increasing the number of voids formed.

A second potential problem with a thick liner layer relates to the rate of the etching process. The step of etching through the liner layer in order to form contact vias might not occur at the same rate on every part of the liner layer. While the liner layer has traditionally provided some protection against “over-etching” in the areas that etch more quickly; however, when etching through a thicker liner layer, the over-etching may be so exacerbated as to etch through the liner as well and cause damage to the underlying transistors. Therefore, the present invention suggests forming a second “etch-stop” layer underneath the liner that is resistant to the etch process. It is helpful if this second “etch-stop” layer is selected from a material that is also resistant to the etch process for removing the liner. Persons of ordinary skill in the art of semiconductor fabrication will be capable of choosing suitable materials for these layers that exhibit these properties.

To the accomplishment of the foregoing and related ends, the following description and annexed drawings set forth in detail certain illustrative aspects and implementations of the invention. These are indicative of but a few of the various ways in which one or more aspects of the present invention may be employed. Other aspects, advantages and novel features of the invention will become apparent from the following detailed description of the invention when considered in conjunction with the annexed drawings.

### BRIEF DESCRIPTION OF THE DRAWINGS

FIGS. 1A-1D are side elevation views in section illustration a portion of a transistor.

FIG. 2 is a flow diagram illustrating an exemplary method of forming a transistor according to one or more aspects of the present invention.

FIG. 3 is a side elevation view in section illustrating a portion of a transistor created according to one or more aspects of the present invention.

### DETAILED DESCRIPTION OF THE INVENTION

One or more aspects of the present invention are described with reference to the drawings, wherein like reference numerals are generally utilized to refer to like elements throughout, and wherein the various structures are not necessarily drawn to scale. In the following description, for purposes of explanation, numerous specific details are set forth in order to provide a thorough understanding of one or more aspects of the present invention. It may be evident, however, to one skilled in the art that one or more aspects of the present invention may be practiced with a lesser degree of these specific details. In other instances, well-known structures and devices are shown in block diagram form in order to facilitate describing one or more aspects of the present invention.

The invention relates to a method of increasing the magnitude of mechanical strain imposed on a transistor in a semiconductor in order to enhance the performance of the transistor. The invention arises in part from the discovery that the amount of mechanical strain imposed on the transistor is related to the amount of liner material deposited over the transistor. Depositing a comparatively thick layer of liner material while fabricating the semiconductor may increase the amount of mechanical strain exerted on the transistor, thereby increasing the carrier mobility throughout the device and enhancing the performance of the transistor. This discovery can be extended to the general concept that for any strain-inducing material that may be deposited over the transistor, the magnitude of mechanical strain exerted on the transistor varies in relation to the thickness of the strain-inducing material so deposited.

As one example of a “thick” layer of strain-inducing material, it is submitted that conventional fabrication processes often involve the deposition of a liner material layer approximately 800 angstroms in thickness. It has been discovered that a layer of liner material of approximately 1500 angstroms in thickness results in a transistor exhibiting greater mechanical strain and faster performance than a transistor with a liner layer measuring 800 angstrom in thickness. However, these measurements are not intended to serve as quantitative definitions, ranges, or limitations of the term “thickness,” but only to illustrate that a comparatively thick layer of strain-inducing material exerts measurably greater mechanical strain on the underlying components, and results in better transistor performance.

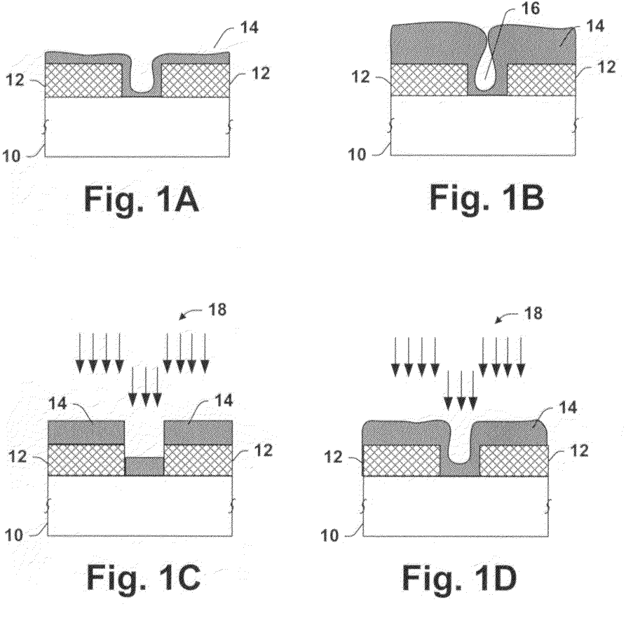

However, certain problems might arise when a comparatively thick layer of strain-inducing material is deposited on the semiconductor. As illustrated in FIGS. 1A-1D, various deposition processes may result in different properties of the layers so deposited. According to a typical process for fabricating semiconductors, the liner layer (sometimes referred to a PMD (pre-metal dielectric) liner) is deposited by chemical vapor deposition (CVD), which is a generally conformal-type deposition process, as shown in FIG. 1A. The deposition forms a layer of material 14 on all exposed surfaces 12, which expands in layer depth across all exposed surfaces as the deposition process continues. The conformal nature of CVD might create a problem when attempting to deposit a layer of material between two nearby structures. As shown in FIG. 1B, a conformal-type deposition process may cause the amount of deposited material 14 deposited on the exposed surfaces of various structures 12 on the semiconductor 10 to vary to a limited extent. If an upper portion of the layer of deposited material 14 fills conformally against the side walls of two nearby structures or features 12 faster than a lower portion of the material 14, then the upper portion of the deposited material layer 14 may close off before the lower portion has been completely filled. The result is a “void” 16 in the deposited material layer 14, comprising a gap or space in the portion of the deposited material layer 14 between two lower portions of the side walls of nearby structures 12 on the semiconductor 10 that cannot be filled by additional deposition. Where the layer serves an electrical isolation function for the semiconductor, a void in the deposited layer may create electrical fluctuations and instabilities in the resulting circuit or subsequent process variations, and is therefore undesirable.

The formation of voids may be especially prevalent between nearby devices, and is therefore of growing importance in light of the trend of semiconductor miniaturization, where the semiconductor contains a growing number of transistors in a semiconductor of decreasing size. Moreover, the conformal deposition of a thicker liner may exacerbate the formation of voids. It may have been the case that a certain ratio of transistor proximity to layer thickness exceeded a desired tolerance of void formation, thereby limiting the circuit design options in light of these parameters. It will be appreciated that a technique for reducing the problem of void formation may shift the ratio of transistor proximity to layer thickness that produces circuits within acceptable fabrication tolerances, and therefore expands the range of design options.

The present invention contemplates the potential occurrence of this void-formation problem while depositing comparatively thick strain-inducing layers, and seeks to ameliorate it. One solution to this problem according to one embodiment of the invention is the use of a primarily directional deposition method, such as that illustrated in FIG. 1C. A primarily directional deposition method deposits the material 14 in a substantially directional manner 18. This filling method causes all gaps and spaces, including those between nearby structures or features 12, to fill in a bottom-up manner, thereby reducing the potential for void formation. A primarily directional deposition method that may be appropriate for this task according to one embodiment of the invention is sputtering. Another solution to this problem according to another embodiment is the use of a partially conformal and partially directional deposition method, such as that illustrated in FIG. 1D, which combines conformal deposition with downward filling. A hybrid process may produce a layer of deposited material 14 that is moderately deposited in a conformal manner along the side walls of nearby devices 12 on the semiconductor 10, and that is also deposited more heavily in a specific direction 18 that will fill gaps and spaces between nearby devices 12. A partially conformal and partially directional deposition method that may be appropriate for this task according to one embodiment is a hybrid CVD/sputtering deposition.

Another property of strain-inducing materials (for example, the liner layer) that may create problems with thicker depositions is a certain variance in the rates of etching in different regions of the strain-inducing material, in which some areas may etch through quickly and other areas etch through slowly. For strain-inducing layers of conventional thinness, the etch rate variance in some cases may be tolerable, since it may not vary significantly within the comparatively short period for etching the thin layer. However, when etching thicker strain-inducing layers, the amount of time between the full etching of the quickest areas and the full etching of the slowest areas may be extended. Accordingly, in the areas where strain-inducing material etching occurs quickly, the liner for the strain-inducing layer may be exposed to the etching solution for an extended period of time. This exposure might result in over-etching, wherein the etch solution entirely etches through the liner, or may partially etch the liner such that a subsequent etch step may result in over-etching of the undesirably thin areas of the liner. Either over-etching scenario might result in an undesired complete etching-through of the liner that may subsequently damage the underlying components.

The present invention contemplates the potential occurrence of this etch-rate variance problem while etching comparatively thick strain-inducing layers, and seeks to ameliorate it. One aspect of the present invention involves a method for circumventing this potential problem by introducing an etch-stop layer underneath the liner. This etch-stop layer may be formed with a material that is comparatively resistant to the etch process for the strain-inducing material etch, and/or is comparatively resistant to the etch process for the overlying liner. In either case, the etch-stop layer serves to protect the underlying components from damage in the event of an etching-through of the liner. As an optional step, the strain-inducing liner may be planarized, for example by chemical mechanical polishing (CMP), in order to provide a surface of consistent width prior to depositing the dielectric material, which promotes the deposition of the dielectric layer having a consistent thickness. As an additional or alternative optional step, the strain-inducing liner may be laminated (e.g., increasing its thickness) in order to increase the magnitude of strain imparted to the transistor.

In another aspect of the invention that is pertinent to the etch-rate variance problem described herein, the present invention comprises a bi-layer liner for a strain-inducing layer in a semiconductor, comprising a liner deposited over an etch-stop layer that is comparatively resistant to an etching solution for the liner. The strain-inducing layer may be a nitride material, or any other material that imparts a strain on the underlying transistor. The etch-stop layer maybe comprised, e.g., of a silicon carbon nitride (SiCN), a silicon carbide (SiC), or a silicon oxynitride (SiON), while the liner is comprised of a nitride in one embodiment. Alternatively, the liner may comprise an oxynitride, a silicon rich nitride layer, or other stress-inducing materials, and all such alternatives and combinations thereof are contemplated as falling within the scope of the invention. The different compositions of these layers give rise to a multitude of etch chemistries to which the liner and/or strain-inducing material are comparatively sensitive, and to which the etch-stop layer is comparatively resistant.

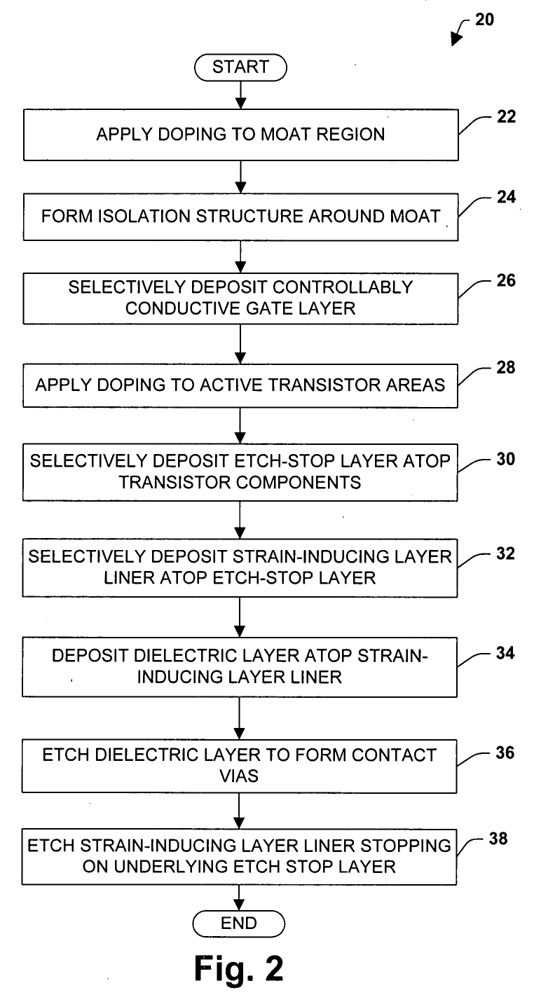

Turning to the figures, an exemplary method in accordance with one or more aspects of the present invention is illustrated in FIG. 2. While the exemplary method is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention.

The method 20 begins with the doping of the moat region 22 and the formation of an isolation structure around the moat 24. A transistor gate structure is devised at 26 by selectively depositing a controllably conductive layer to serve as the gate of the transistor. At 28, the active areas of the transistor are doped in accordance with the desired electrical property of the transistor; in one embodiment NMOS transistors are n-doped, and PMOS transistors are p-doped. Any appropriate doping method may be used for this step, such as, for example, ion implantation.

At 30, an etch-stop layer is deposited over the transistor components. At 32, a strain-inducing layer liner is deposited over the etch-stop layer. The strain-inducing layer liner and etch-stop layer are comprised of materials selected in light of an etching solution to which the strain-inducing layer liner is comparatively sensitive, and to which the etch-stop layer is comparatively resistant. As one set of examples, the etch-stop layer may comprise a silicon carbon nitride (SiCN), a silicon carbide (SiC), or a silicon oxynitride (SiON), while the strain-inducing layer liner may comprise, for example, a nitride, oxynitride, silicon rich nitride, or other suitable material. For such configurations, a number of etch solutions may be selected to which the strain-inducing layer liner is comparatively sensitive, and to which the etch-stop layer is comparatively resistant.

The deposition of a strain-inducing layer liner at 32 may optionally be followed by one or both of the following steps that are also in accordance with one embodiment of the present invention. As one option, the strain-inducing layer liner may be planarized in order to provide a substrate of consistent width on which to deposit the dielectric layer. Any appropriate means of planarization may be used; as one example, the semiconductor may be subjected to chemical mechanical polishing (CMP). This optional step reduces variance in the dielectric layer deposited at 34, thereby leading to enhanced process control. As another optional step, the strain-inducing layer liner may be laminated or increased in thickness in order to increase the magnitude of strain imparted to the transistor.

In one embodiment of the invention, the liner layer deposited at 32 is performed in at least a partially directional manner to avoid voiding in the deposited layer between features that are close together, such as gate structures of neighboring devices. As discussed herein, the selected deposition method may produce different forms of strain-inducing layers, especially in light of the comparative thickness of the strain-inducing layer as recommended herein. A purely conformal deposition method, such as chemical vapor deposition (CVD), might create voids that result in electrical fluctuations and instabilities in the resulting circuit. A better result may be obtained by using a substantially directional deposition method, such as sputtering, or by using a partly conformal and partly directional deposition method, such as a hybrid CVD/sputtering deposition method. In the above manner, the liner layer is formed to a greater thickness than conventional liner layers, and such thicker layers do not exhibit voids, etc. that heretofore disadvantageously occurred.

The method illustrated in FIG. 2 continues at 34 with the deposition of a dielectric layer over the strain-inducing layer liner.

The method illustrated in FIG. 2 continues further at 36 with the etching of the dielectric layer, using an etching solution or chemistry to which the dielectric layer is sensitive. Finally, at 38, the underlying strain-inducing layer liner (now exposed after the dielectric via etch) is etched with an etching solution or chemistry to which the strain-inducing layer liner is comparatively sensitive, and to which the underlying etch-stop layer is comparatively resistant. The result of this method is a transistor featuring a comparatively thick strain-inducing layer liner, an absence of performance-damaging voids in the thick strain-inducing layer liner, and components underlying the etch-stop layer that are undamaged by potential over-etching of the strain-inducing layer liner, as described herein. The invention encompasses transistors made according to the process described hereinabove.

In another aspect, the invention recites a bi-layer liner that includes a thick strain-inducing layer liner. The bi-layer liner comprises a thick strain-inducing layer liner over an etch-stop layer, where the materials that comprise each layer are selected such that an etch solution may be selected to which the strain-inducing layer liner is comparatively sensitive, and to which the etch-stop layer is comparatively resistant. This bi-layer may be deposed underneath the dielectric layer to provide increased stress and in order to reduce the risk of damage to components underneath the bi-layer due to over-etching, as described herein.

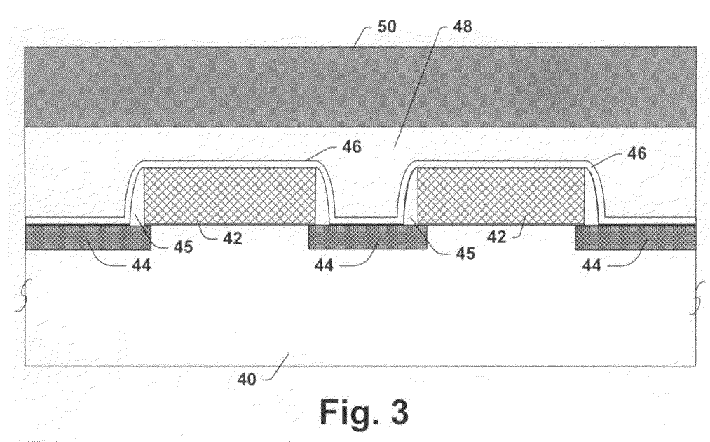

An exemplary transistor formulated in accordance with the present invention, and incorporating this bi-layer liner, is illustrated in FIG. 3. A portion of a silicon substrate 40 is doped according to the type of transistor to be supported: a portion of the substrate that will support NMOS devices is p-doped, while a portion of the substrate that will support PMOS devices is n-doped. The portion may be electrically isolated from other portions of the silicon substrate by creating an isolation structure (not shown.) A conductive layer such as polysilicon 42 is deposited on the semiconductor substrate 40 over a gate dielectric layer (not shown) in such a manner as to span a plurality of active transistor areas 44, and is patterned to form transistor gate regions. Sidewall spacers 45 are typically formed on lateral edges of the gate structures 42, as illustrated. The active transistor areas may be doped in accordance with the desired electrical properties of the device, e.g., n-doping for an NMOS device, or p-doping for a PMOS device to form the source/drain regions 44. In many cases, the semiconductor is subjected to silicidation in order to produce a silicide layer (not shown) over the transistor gate and active areas as an additional etch-stop protector.

Following the formation of the transistor gate 42 and possibly a silicide layer (not shown), an etch-stop layer 46 is deposited over the transistors. Over the etch-stop layer 46 is deposited a thick strain-inducing layer liner 48. As discussed herein, the etch-stop layer 46 and strain-inducing layer liner 48 are comprised of materials such that an etching solution may be selected to which the strain-inducing layer liner 48 is comparatively sensitive, but to which the etch-stop layer 46 is comparatively resistant.

As discussed herein, a comparatively thick strain-inducing liner layer 48 may be advantageous for exerting greater mechanical strain on the transistor gate 42 and/or active transistor areas 44. Also as discussed herein, the method of depositing the strain-inducing liner layer 48 may lead to different types of deposited thick strain-inducing liner layers. The exemplary transistor shown in FIG. 3 is illustrated with a strain-inducing liner layer 48 formed by a primarily directional deposition method, which thereby reduces the potential for forming a void therein between neighboring features, such as the two semiconductor gates 42 shown in close proximity in FIG. 3. Further, as shown, the strain-inducing liner layer 48 may be planarized, for example, via CMP to facilitate subsequent processing.

Over the stain-inducing layer liner 48 is deposited a dielectric layer 50. A helpful choice for the material comprising the strain-inducing layer is a dielectric, which also protects the semiconductor from undesired electrical or mechanical shock. The transistor fabrication is completed by selectively etching the dielectric layer 50 in a first etch step, and then selectively etching the strain-inducing layer liner 48 in a second etch step to form contact vias (not shown) down to the gate 42 and source/drain regions 44. These etches may be carried out for an extended period of time in order to ensure the complete etching of each layer, because the formation of the etch-stop layer 46 protects the underlying components, such as the transistor gate 42, from over-etching damage. The transistor illustrated in FIG. 3 and fabricated as described herein thus features a thick strain-inducing liner layer that exerts an enhanced mechanical strain on the transistor gate 42 and/or active transistor areas 44, thereby improving the performance of the transistor.

It will be appreciated that the steps of this method shown in FIG. 2 may be performed, and the isolation structure shown in FIG. 3 may be formed, using any suitable technique selected from the several alternative techniques known to those of ordinary skill in the art of semiconductor fabrication. For instance, the doping of the moat region and the active transistor areas may each occur in several positions in this method without altering the resulting properties of the semiconductor.

It will be appreciated that while reference is made throughout this document to exemplary structures in discussing aspects of methodologies described herein, those methodologies are not to be limited by the corresponding structures presented. Rather, the methodologies (and structures) are to be considered independent of one another and able to stand alone and be practiced without regard to any of the particular aspects depicted in the Figs.

It is also to be appreciated that layers and/or elements depicted herein are illustrated with particular dimensions relative to one another (e.g., layer to layer dimensions and/or orientations) for purposes of simplicity and ease of understanding, and that actual dimensions of the elements may differ substantially from that illustrated herein.

Additionally, it will be appreciated that the ordering of the acts or events of the methods described herein can also be altered. For example, NMOS doping may occur at one of several points in this method; as long as the resulting transistor forms a controllably conductive gate between a plurality of NMOS active transistor areas in a PMOS active region, the resulting transistor will operate as intended.

Additionally, unless stated otherwise and/or specified to the contrary, any one or more of the layers set forth herein can be formed in any number of suitable ways, such as with spin-on techniques, sputtering techniques (e.g., magnetron and/or ion beam sputtering), (thermal) growth techniques and/or deposition techniques such as atomic layer deposition (ALD), chemical vapor deposition (CVD), physical vapor deposition (PVD), atmospheric pressure CVD (APCVD), low pressure CVD (LPCVD), metal-organic CVD (MOCVD) and/or plasma enhanced CVD (PECVD), for example, and can be patterned in any suitable manner (unless specifically indicated otherwise), such as via etching and/or lithographic techniques, for example.

Although the invention has been shown and described with respect to one or more implementations, equivalent alterations and modifications will occur to others skilled in the art based upon a reading and understanding of this specification and the annexed drawings. The invention includes all such modifications and alterations and is limited only by the scope of the following claims. In particular regard to the various functions performed by the above described components (assemblies, elements, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.” Also, “exemplary” as utilized herein merely means an example, rather than the best.

What is claimed is:

1. A method of forming a transistor in a semiconductor substrate, the method comprising:
forming a transistor gate that spans a plurality of active regions on the semiconductor substrate;
forming an etch-stop layer over the transistor gate; and
forming a strain-inducing layer liner over the etch-stop layer that is comparatively sensitive to an etch to which the etch-stop layer is comparatively resistant; and
forming a dielectric layer over the strain-inducing layer liner.

2. The method of claim 1, further comprising: after forming the strain-inducing layer liner and before forming the dielectric layer, planarizing the strain-inducing layer liner.

3. The method of claim 1, wherein the strain-inducing layer liner is laminated.

4. The method of claim 1, where the strain-inducing layer liner is formed by a primarily directional deposition process.

5. The method of claim 4, where the primarily directional deposition process comprises a sputtering deposition.

6. The method of claim 1, where the strain-inducing layer liner is formed by a partly directional and partly conformal deposition process.

7. The method of claim 6, where the partly directional and partly conformal deposition process comprises a hybrid chemical vapor deposition and sputtering process.

8. The method of claim 1, where the dielectric layer further comprises a strain-inducing layer.

9. The method of claim 1, where the etch-stop layer comprises a silicon oxynitride, and where the strain-inducing layer liner comprises a nitride.

10. The method of claim 1, where the etch-stop layer comprises a silicon carbide, and where the strain-inducing layer liner comprises a nitride.

11. The method of claim 1, where the etch-stop layer comprises a silicon carbon nitride, and where the strain-inducing layer liner comprises a nitride.

12. A transistor in a semiconductor substrate produced according to the method of claim 1.

13. A bi-layer liner for a thick strain-inducing layer of a transistor in a semiconductor substrate, the bi-layer liner comprising:
an etch-stop layer, and
a strain-inducing layer liner over the etch-stop layer that is comparatively sensitive to an etch to which the etch-stop layer is comparatively resistant.

14. The bi-layer liner of claim 13, where the strain-inducing layer liner has a planarized top surface.

15. The bi-layer liner of claim 13, where the strain-inducing layer liner has a laminated surface.

16. The bi-layer liner of claim 13, where the etch-stop layer comprises a silicon oxynitride, and where the strain-inducing layer liner comprises a nitride.

17. The method of claim 17, where the etch-stop layer comprises a silicon carbide, and where the strain-inducing layer liner comprises a nitride.

18. The method of claim 13, where the etch-stop layer comprises a silicon carbon nitride, and where the strain-inducing layer liner comprises a nitride.

19. The method of claim 13, wherein the strain-inducing layer liner comprises a nitride, an oxynitride, or a silicon rich nitride.

20. A transistor in a semiconductor substrate, the transistor comprising:
two transistor gates overlying the semiconductor substrate, and defining a space therebetween;
an etch-stop layer over the transistor gate;
a strain-inducing layer liner over the etch-stop layer formed by at least a partially directional deposition process, wherein the strain-inducing layer liner is suffiently thick so as to substantially fill the space between the transistor gates without voiding therein; and
a dielectric layer over the strain-inducing layer liner.
